(19) United States
(12) Patent Application Publication
(10) Pub. No.: US 2008/0280379 A1
(43) Pub. Date: Nov. 13, 2008

(54) METHOD OF MANUFACTURING THIN FILM TRANSISTOR SUBSTRATE AND MANUFACTURING SYSTEM USING THE SAME

(75) Inventors: Min-Seok OH, Yongin-si (KR); Sang-Gab KIM, Seoul (KR); Hong-Kee CHIN, Suwon-si (KR); Yu-Gwang JEONG, Yongin-si (KR); Seung-Ha CHOI, Shiheung-si (KR); Ki-Hyun KIM, Cheonan-si (KR); In-Ho SONG, Seoul (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/933,413

(22) Filed: Oct. 31, 2007

(30) Foreign Application Priority Data
Nov. 3, 2006 (KR) 10-2006-0108416

(51) Int. Cl. H01L 21/66; H01L 21/67

(52) U.S. Cl. 438/5; 156/345.24

(57) ABSTRACT

Provided is a method of manufacturing a thin film transistor substrate and a manufacturing system using the same, wherein the production of corrosive substances is reduced during the process of manufacturing the thin film transistor substrate. The method includes providing an etching unit with an insulation substrate on which a thin metal film has been deposited, and dry-etching the insulation substrate so as to form a predetermined circuit pattern; providing a waiting unit with the insulation substrate waiting to be cleaned; performing a preliminary cleaning operation by a cleaning unit having a plurality of nozzles while the insulation substrate waits and checking the preliminary cleaning operation; and performing a main cleaning operation with regard to the insulation substrate based on the result of the check.

### CROSS-REFERENCE TO RELATED APPLICATION

This application claims priority from and the benefit of Korean Patent Application No. 10-2006-0108416, filed on Nov. 3, 2006, which is hereby incorporated by reference for all purposes as if fully set forth herein.

### BACKGROUND OF THE INVENTION

1. Field of the Invention

The present invention relates generally to a method of manufacturing a thin film transistor substrate and a manufacturing system using the same. More particularly, the present invention relates to reducing the production of corrosive substances during the process of manufacturing the thin film transistor substrate.

2. Discussion of the Background

As LCD's increase in size, methods are needed for reducing the resistance of the gate and source/drain wirings of the thin film transistor (TFT) substrates and ensuring that the respective wirings are formed on a micro-scale in order to increase the aperture ratio and improve the quality of the LCD's.

To make such improvements, a multilayered thin metal film may be used for the gate and source/drain wirings when a TFT substrate is manufactured. The thin metal film is dry-etched and cleaned.

However, during the process of dry-etching and cleaning the thin metal film, the etching gas remaining on the thin metal film produces corrosive substances resulting from metal oxide. Such corrosive substances result in defective LCD's.

### SUMMARY OF THE INVENTION

The present invention provides a method of manufacturing a TFT substrate, wherein the production of corrosive substances may be reduced.

The present invention also provides a system for manufacturing a TFT substrate that uses the above-mentioned method.

Additional features of the invention will be set forth in the description which follows, and in part will be apparent from the description, or may be learned by practice of the invention.

The present invention discloses a method of manufacturing a thin film transistor substrate, the method including providing an etching unit with an insulation substrate including a thin metal film, and dry-etching the insulation substrate to form a circuit pattern; providing a waiting unit for the insulation substrate waiting to be cleaned; performing a preliminary cleaning operation by a cleaning unit having a plurality of nozzles while the insulation substrate waits, and checking the preliminary cleaning operation; and performing a main cleaning operation with regard to the insulation substrate based on a result of the check.

The present invention also discloses a system for manufacturing a thin film transistor substrate, the system including an etching unit to dry-etch an insulation substrate and a thin metal film deposited on the insulation substrate to form a circuit pattern; a waiting unit to receive the insulation substrate from the etching unit; a cleaning unit including a plurality of nozzles, the cleaning unit to receive the insulation substrate from the waiting unit and perform a main cleaning operation; a transfer unit positioned between the waiting unit and the cleaning unit to transfer the insulation substrate; and a control unit to control the cleaning unit to perform a preliminary cleaning operation while the insulation substrate waits in the waiting unit, the control unit to check whether the cleaning unit operates normally and determine the main cleaning operation of the insulation substrate based on a result of the checking.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a flowchart showing a process of manufacturing an LCD.

FIG. 2 is a flowchart showing a method of manufacturing a TFT substrate according to an exemplary embodiment of the present invention.

FIG. 3 is a block diagram showing a manufacturing system used for the method shown in FIG. 2.

FIG. 4, FIG. 5, FIG. 6, FIG. 7, FIG. 8, FIG. 9, FIG. 10, FIG. 11, FIG. 12, FIG. 13, and FIG. 14 are sectional views showing intermediate structures of a method of manufacturing a TFT substrate according to an exemplary embodiment of the present invention.

FIG. 15, FIG. 16, FIG. 17, FIG. 18, and FIG. 19 are sectional views showing intermediate structures in a method of manufacturing a TFT substrate according to another exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

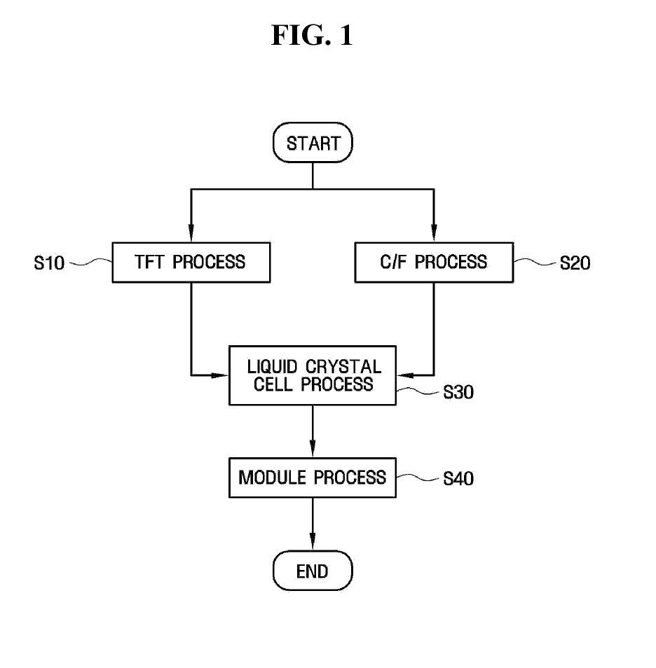

FIG. 1 is a flowchart showing a process of manufacturing an LCD.

Referring to FIG. 1, the process of manufacturing an LCD includes a TFT process (S10), a C/F process (S20), a liquid crystal cell process (S30), and a module process (S40).

During the TFT process (S10), a TFT substrate may be manufactured by forming a TFT and a pixel electrode on an insulation substrate. During the C/F process (S20), a color filter substrate may be manufactured by forming a color filter (CF) and a common electrode on an insulation substrate. During the liquid crystal cell process (S30), the TFT substrate and the color filter substrate manufactured in the TFT process (S10) and the C/F process (S20), respectively, are bonded to each other with a gap between them, and liquid crystal is injected between them so as to manufacture a liquid crystal panel. During the module process (S40), the liquid crystal panel manufactured during the liquid crystal cell process (S30) is coupled to another module to complete the LCD.

Each of the above-mentioned processes may include a number of detailed steps. For example, the TFT process (S10) may include steps for thin film formation, deposition, photolithography, and etching, which are repeated as in the case of a process of manufacturing a silicon semiconductor, as well as inspection and cleaning steps performed before and after each step.

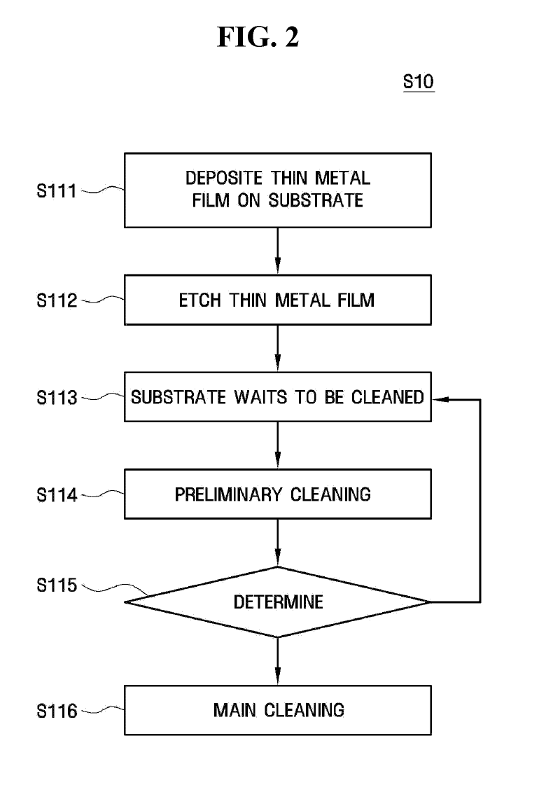

The TFT process will now be described in detail with reference to FIGS. 2 through 19.

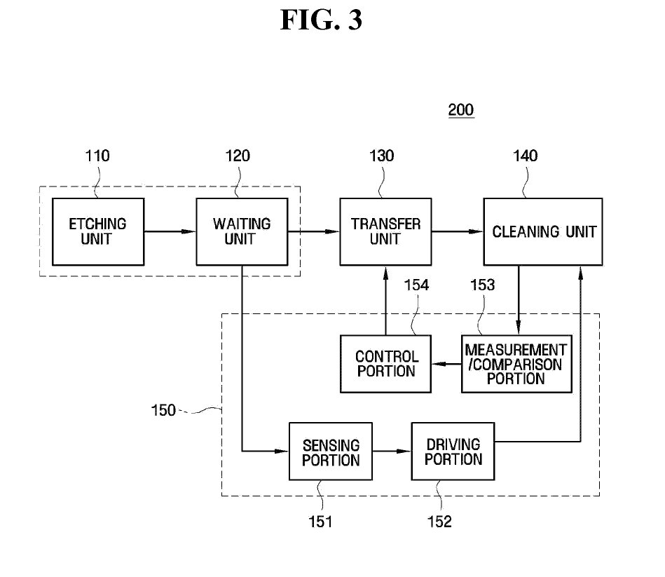

FIG. 2 is a flowchart showing a method of manufacturing a TFT substrate according to an exemplary embodiment of the present invention, and FIG. 3 is a block diagram showing a manufacturing system using the method shown in FIG. 2.

Referring to FIG. 2, the method of manufacturing a TFT substrate includes a step of depositing a thin metal film on a substrate (S111), a step of etching the thin metal film (S112), a step of waiting for the substrate to be cleaned (S113), a step of preliminary cleaning (S114), and a step of main cleaning (S116). The method may further include a step of determining whether the cleaning operation is conducted as desired (S115) between the step of preliminary cleaning (S114) and the step of main cleaning (S116). The step of etching the thin metal film (S112) may be performed repeatedly.

Referring to FIG. 3, a system 200 for manufacturing a TFT substrate may include an etching unit 110, a waiting unit 120, a transfer unit 130, a cleaning unit 140, and a control unit 150. The control unit 150 may include a sensing portion 151, a driving portion 152, a measurement/comparison portion 153, and a control portion 154. The cleaning unit 140 may have a plurality of nozzles (not shown) for spraying a cleaning liquid.

The operation of the system 200 for manufacturing a TFT substrate will now be described in more detail with reference to FIG. 2 and FIG. 3.

A thin metal film is deposited on a substrate (S111) such as an insulation substrate made of transparent glass or plastic, according to a predetermined method, e.g. sputtering.

After depositing the thin metal film, the substrate is moved to the etching unit 110 so as to etch the deposited thin metal film (S112). The method for etching the thin metal film may include dry etching and wet etching. In the present exemplary embodiment, the dry etching method is employed so as to control the depth of etching of the thin metal film on a micro-scale. The gas used during the etching may be a Cl-based gas. However, the type of the gas is not limited to that in the present invention, and may be selected from Cl, HCL, BCl, SF₆, CF₄, and a combination of at least two of these gases.

After being etched, the substrate is moved to the waiting unit 120, in which the substrate waits to be cleaned (S113). The etching unit 110 and the waiting unit 120 may be vacuum chambers.

While the substrate waits to be cleaned in the waiting unit 120 (S113), the cleaning unit 140 is driven for a predetermined time to perform a preliminary cleaning operation (S114). More particularly, when the substrate is moved from the etching unit 110 to the waiting unit 120 after being etched, the sensing portion 151 of the control unit 150 senses the substrate inside the waiting unit 120 and provides a corresponding signal to the driving portion 152. The sensing portion 151 may be light-emitting/light-receiving diodes.

Upon receiving the signal from the sensing portion 151, the driving portion 152 drives the cleaning unit 140 for a predetermined time before the substrate is moved to the cleaning unit 140 to perform a preliminary cleaning operation of spraying a cleaning liquid via a plurality of nozzles for about 1-5 seconds (S114).

The control unit 150 then determines whether the cleaning unit 140 is operating normally (S115). Particularly, the measurement/comparison portion 153 of the control unit 150 measures the amount of cleaning liquid sprayed during the preliminary cleaning operation of the cleaning unit 140, and compares the measured amount with a reference value. Based on the result from the measurement/comparison portion 153, the control portion 154 determines whether or not to transfer the substrate.

When the amount of cleaning liquid measured by the measurement/comparison portion 153 is less than the reference value, the control portion 154 does not drive the transfer unit 130, but causes the substrate to wait inside the waiting unit 120. After an abnormal operation, if any, of the cleaning unit 140 is corrected, the preliminary cleaning operation of the cleaning unit 140 (S114) is performed again. The main cleaning of the substrate may now be performed (S116).

When the amount of cleaning liquid measured by the measurement/comparison portion 153 is substantially equal to or greater than the reference value, the control portion 154 causes the substrate to be transferred to the cleaning unit 140. The control portion 154 drives the transfer unit 130 based on the result from the measurement/comparison portion 153. Then, the transfer unit 130 moves the substrate from the waiting unit 120 to the cleaning unit 140.

As such, the substrate, which has been etched by the etching unit 110, waits in the waiting unit 120, which is maintained in a vacuum, before being subjected to a cleaning process. This decreases the time of exposure of the substrate to the air for the cleaning process and, as a result, reduces the amount of corrosive substances produced from the gas remaining on the surface of the thin metal film.

The transfer unit 130 may be a robot arm.

The cleaning unit 140 receives the substrate from the transfer unit 130 and performs a main cleaning operation (S116). The cleaning liquid sprayed via the nozzles of the cleaning unit 140 may be high-temperature deionized (DI) water, but the cleaning liquid is not limited to that of the present invention. The cleaning unit 140 may perform the main cleaning operation with regard to the etched substrate by using DI water having a temperature of about 80-100° C. (S116).

Although not shown in the drawing, an additional transfer unit 130 may be positioned between the etching unit 110 and the waiting unit 120 so as to transfer the substrate.

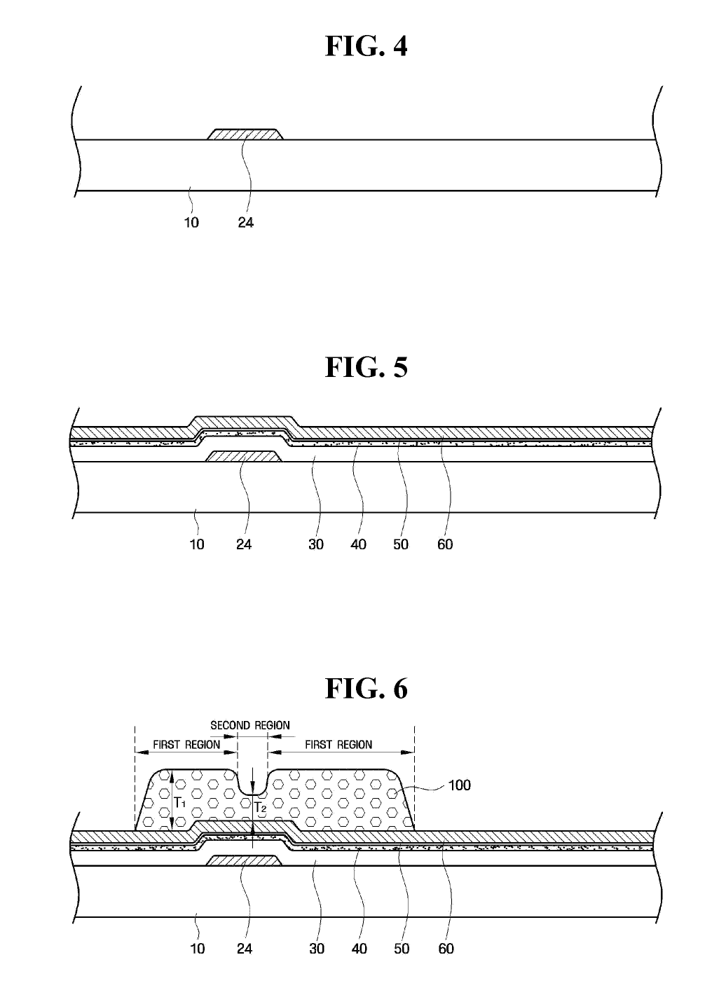

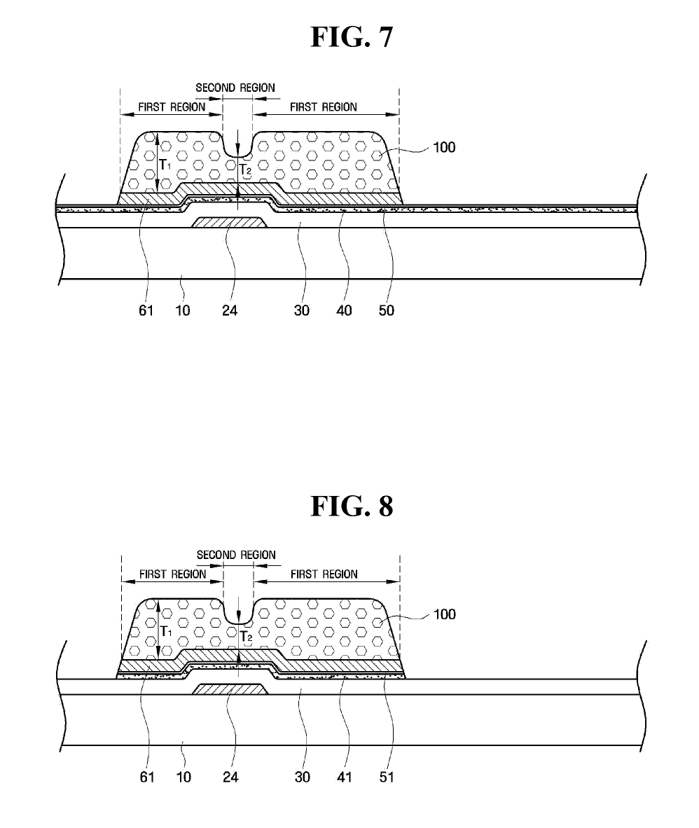

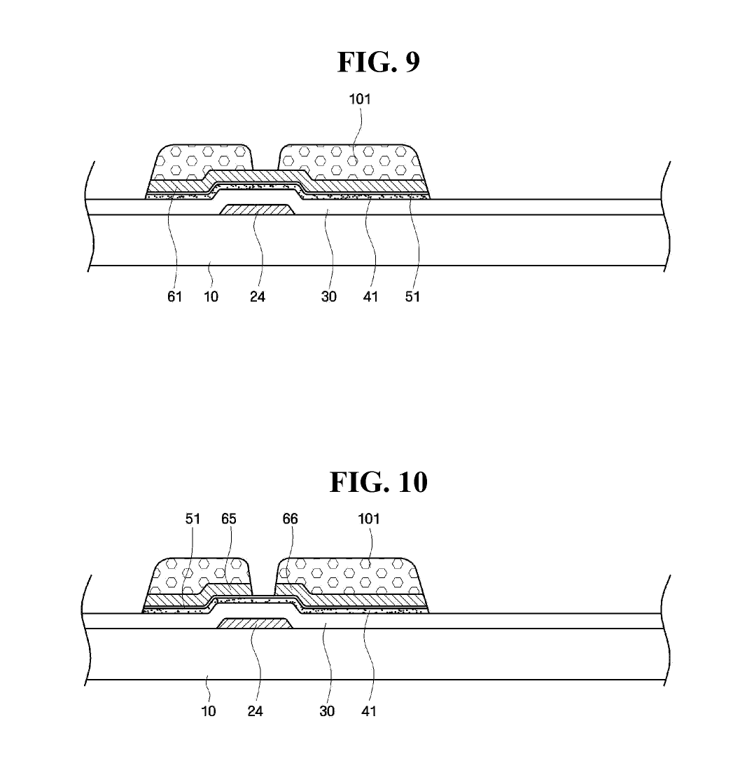

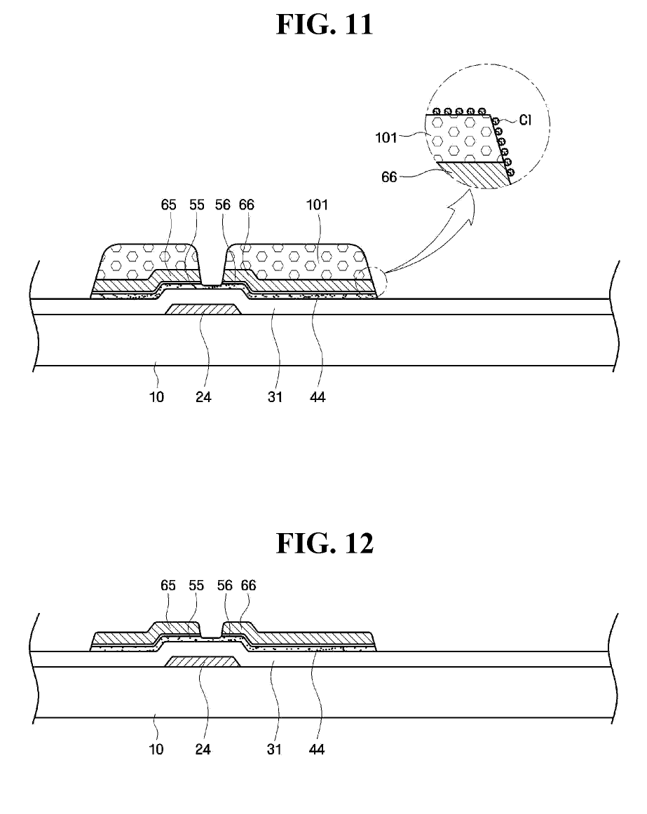

The above-mentioned method of manufacturing a TFT substrate will now be described in more detail with reference to FIGS. 2 through 14. FIGS. 4 through 14 are sectional views showing intermediate structures of a method of manufacturing a TFT substrate according to an exemplary embodiment of the present invention. Description of the present exemplary embodiment will be made with reference to FIGS. 4 through 14, as well as to FIGS. 2 and 3. For clarity, it will be assumed in the following description that four masks are used to manufacture a TFT substrate. The method of manufacturing a TFT substrate according to an exemplary embodiment of the present invention shown in FIG. 2 is applied to a process for forming a data wiring of a TFT substrate requiring micro-scale wiring patterns. However, those skilled in the art can easily understand that the present invention is not limited to that assumption, and is also applicable to a process for forming a gate wiring.

Referring to FIG. 4, a gate conductive layer is stacked on the front surface of an insulation substrate 10 by a predetermined method (e.g. sputtering) and is subjected to photolithography so as to form a gate wiring which includes a gate line (not shown), a gate electrode 24, and a maintenance electrode line (not shown). The gate line, the gate electrode 24, and the maintenance electrode line may be made of a single layer or a multilayer including aluminum (Al), copper (Cu), silver (Ag), molybdenum (Mo), chromium (Cr), titanium (Ti), tantalum (Ta), or an alloy thereof. The gate conductive layer may be etched by the above-mentioned method, i.e., wet etching or dry etching.

Referring to FIG. 2, FIG. 4, and FIG. 5, a gate insulation film 30, an undoped amorphous silicon layer 40, and a doped amorphous silicon layer 50 are formed on the front surface of the resultant shown in FIG. 4. For example, Chemical Vapor Deposition (CVD) or Plasma Enhanced Chemical Vapor Deposition (PECVD) may be used during this step and conducted as a part of continuous deposition or in situ.

The gate insulation film 30 may be made of silicon nitride (SiNx) and may have a deposition thickness of about 1,500-5,000 Å. The undoped amorphous silicon layer 40 may be made of amorphous silicon hydride and may have a deposition thickness of about 500-2,000 Å. The doped amorphous silicon layer 50 may be made of n⁺ amorphous silicon hydride, which has been doped with a high-level of n-type impurities, with a deposition thickness of about 300-600 Å.

Thereafter, a data conductive layer 60 made of a thin metal film is deposited on the doped amorphous silicon layer 50 (S111), as mentioned above. The data conductive layer 60 may be made of a single layer or a multilayer including aluminum (Al), copper (Cu), silver (Ag), molybdenum (Mo), chromium (Cr), titanium (Ti), tantalum (Ta), or an alloy thereof. Preferably, the data conductive layer 60 is made of a substance that can be dry-etched. For example, the data conductive layer 60 may be made of a single layer of molybdenum or titanium, a dual layer of titanium/aluminum, or a triple layer of titanium/aluminum/titanium, titanium/aluminum/titanium nitride, or molybdenum/aluminum/molybdenum. However, the data conductive layer 60 may be made of various materials, and it may have various layered structures. The data conductive layer 60 may be deposited by sputtering.

Referring to FIG. 5 and FIG. 6, a photoresist film is disposed on the data conductive layer 60. The photoresist film may be made of positive-type photoresist including Photo Acid Generator (PAG) and/or negative-type photoresist including Photo Active Crosslinker (PAC). For more precise patterning in the subsequent process, the negative-type photoresist may be used considering that the slant angle of the pattern outside is closer to the right angle.

The photoresist film is then exposed to light and developed so as to define a wiring portion, a first region having a first thickness T₁, a channel portion, and a second region having a second thickness T₂. This provides a first photoresist pattern 100. The second thickness T₂ is smaller than the first thickness T₁. The ratio between the first and second thicknesses T₁ and T₂ of the first photoresist film 100 depends on process conditions required by the etching process (described later). In order to form the first photoresist pattern 100 having different thicknesses, a slit mask or halftone mask may be used.

Referring to FIG. 2, FIG. 3, FIG. 6, and FIG. 7, the first photoresist pattern 100 is used as an etching mask to etch the exposed data conductive layer 60 and form a patterned data conductive layer 61 (S112). The data conductive layer 60 may be dry-etched. Particularly, the insulation substrate 10 having the data conductive layer 60 and the first photoresist pattern 1100 formed thereon is moved to the etching unit 110, which uses a Cl-based gas and etches the data conductive layer 60 so that a patterned data conductive layer 61 is formed. The resulting patterned data conductive layer 61 may have a type of data wiring (described later) including source and drain electrodes 65 and 66.

Referring to FIG. 2, FIG. 7, and FIG. 8, the resultant shown in FIG. 7 is used to etch the doped amorphous silicon layer 50 and the undoped amorphous silicon layer 40, which have been exposed, so that a resistant contact layer pattern 51 and a semiconductor layer pattern 41 are formed (S112). The first photoresist pattern 1100 may be similarly used as an etching mask as in the case of FIG. 7. The etching process in the present exemplary embodiment is substantially the same as the above-mentioned process for etching the data conductive layer 60, and a repeated description thereof will be omitted herein.

Referring to FIG. 8 and FIG. 9, the first photoresist pattern 100 shown in FIG. 8 is etched back to form a second photoresist pattern 101. Particularly, the second region of the first photoresist pattern 100 is removed so that the resulting second photoresist pattern 101 only has a first region. The thickness of the first region of the second photoresist pattern 101 may be less than that of the first region of the first photoresist pattern 100. Then, ashing is performed to remove the remnants of the first photoresist pattern 100 from the surface of the data conductive layer 60 in the channel region.

Referring to FIG. 2, FIG. 9, and FIG. 10, the second photoresist pattern 101 is used as an etching mask to etch the patterned data conductive layer 61 and form a data wiring having a channel region, e.g. a data wiring including a data line (not shown), a source electrode 65, and a drain electrode 66 (S112). The etching process of the present exemplary embodiment may be conducted in substantially the same manner as the above-mentioned process for etching the data conductive layer 60 and the process for etching the amorphous silicon layer 50 and the undoped amorphous silicon layer 40.

Referring to FIG. 2, FIG. 10, and FIG. 11, the etching process is further conducted to remove and separate the resistant contact layer pattern 51 in the channel region so that resistant contact layers 55 and 56 are completed (S112). For complete separation of the resistant contact layers 55 and 56 in the channel region, the underlying semiconductor layer pattern 41 may be partially over-etched to form a semiconductor layer 44. Although this may be conducted on a continuous basis (i.e. in a batch mode) by using the same gas used to etch the patterned data conductive layer 61 (e.g. Cl-based gas), for convenience it is also possible to use a gas other than that used in the step shown in FIG. 10 for more precise control or quicker processing, or to adopt another etching condition.

The above steps complete the data wirings, which include a data line (not shown), a source electrode 65, and a drain electrode 66.

Referring to FIG. 2, FIG. 3, and FIG. 11, after the etching process is over, the insulation substrate 10 is moved from the etching unit 110 to the waiting unit 120, in which the insulation substrate 10 waits to be cleaned (S113). It should be noted that the above-mentioned etching processes may be conducted in a batch mode inside the etching unit 110, which is maintained in a vacuum. The cleaning process may be performed after all etching processes are over, after the etching processes for forming the data wirings.

As shown in FIG. 11, gas (e.g. Cl gas) may remain on the section of the etched thin metal film (e.g. data wirings). The Cl gas may produce corrosive substances, for example, aluminum hydride (Al(OH)₃), as defined by the reaction given below, when the insulation substrate 10 is exposed to the air during cleaning.

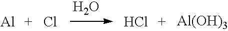

In this regard, according to the present exemplary embodiment, a preliminary cleaning step (S114) for testing the operation of the cleaning unit 140 precedes the main cleaning step (S116) for cleaning the etched insulation substrate 10. This shortens the time of exposure of the insulation substrate 10 to the air.

More particularly, while the insulation substrate 10 waits to be cleaned in the waiting unit 120 (S113), the cleaning unit 140 conducts a preliminary cleaning operation (S114). The control unit 150 checks the cleaning operation of the cleaning unit 140 (S115). If the cleaning operation is normal, the insulation substrate 10 is moved to the cleaning unit 140 by the transfer unit 130 and is subjected to a main cleaning operation (S116). If the cleaning operation is not normal, the insulation substrate 10 remains in the waiting unit 120 (S113).

This minimizes the time of exposure of the insulation 10 to the air during cleaning, as mentioned above, and reduces corrosive substances formed on the etched thin metal film, e.g., data wirings.

Although not shown in FIG. 2, a process for drying the cleaning liquid remaining on the insulation substrate 10 may be performed after the main cleaning operation (S116) of the insulation substrate 10.

Referring to FIG. 11 and FIG. 12, after the insulation substrate 10 has been cleaned, the second photoresist pattern 101 is completely removed from the insulation substrate 10 by using a photoresist pattern stripper.

Referring to FIG. 12 and FIG. 13, a protective film 70 is stacked on the front surface of the resultant shown in FIG. 12 by using CVD or PECVD.

The protective film 70 is patterned to form a contact hole 76 for partially exposing the drain electrode 66.

Finally, referring to FIG. 13 and FIG. 14, a conductive film (e.g. ITO layer) is stacked on the resultant shown in FIG. 13 with a thickness of 400-500 Å and is patterned so as to form a pixel electrode 82 connected to the drain electrode 66. This completes a TFT substrate as shown in FIG. 14.

Although a method of manufacturing a TFT substrate according to an exemplary embodiment of the present invention has been described with reference to a four-mask process for a TFT substrate, the present invention is not limited to that in any manner. A method of manufacturing a TFT substrate according to another exemplary embodiment of the present invention will now be described with reference to a five-mask process for a TFT substrate.

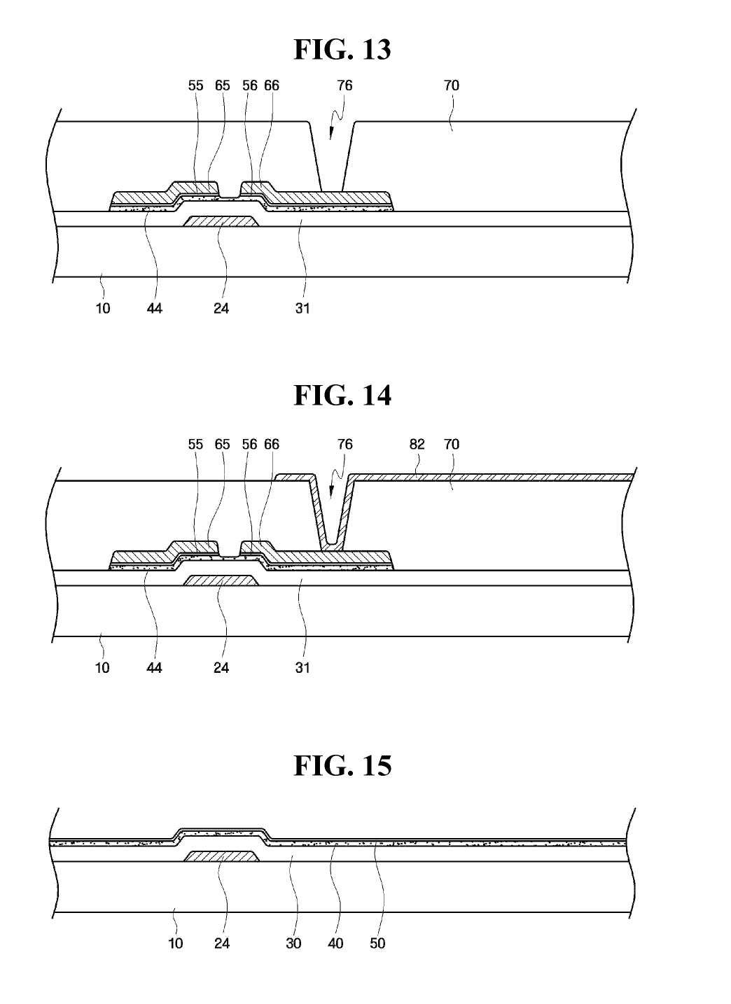

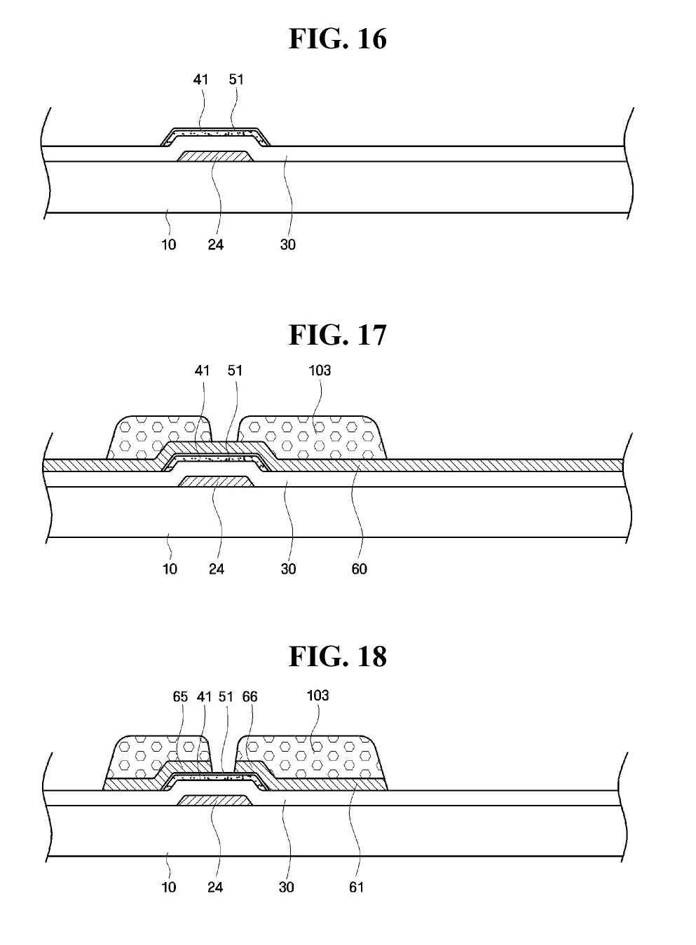

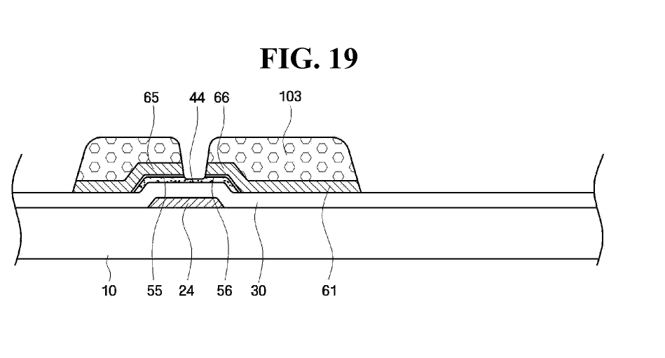

FIGS. 15 through 19 are sectional views showing intermediate structures of a method of manufacturing a TFT substrate according to another exemplary embodiment of the present invention.

As shown in FIG. 4, a gate wiring, which includes a gate line (not shown), a gate electrode 24, and a maintenance electrode line (not shown), is formed on an insulation substrate 10.

Referring to FIG. 15, a gate insulation film 30, an undoped amorphous silicon layer 40, and a doped amorphous silicon layer 50 are formed on the front surface of the insulation substrate 10 so as to cover the gate electrode 24. The method of forming the gate wiring, the gate insulation film 30, the undoped amorphous silicon layer 40, and the doped amorphous silicon layer 50 may be substantially similar to the method described with regard to the previous exemplary embodiment.

Referring to FIG. 15 and FIG. 16, the doped amorphous silicon layer 50 and the undoped amorphous silicon layer 40 are etched to form a resistant contact layer pattern 51 and a semiconductor layer pattern 41. Particularly, a photoresist film is applied to the resultant shown in FIG. 15, and is patterned through a photolithography/etching process. The resulting photoresist film is used as an etching mask to etch the doped amorphous silicon layer 50 and the undoped amorphous silicon layer 40 through a dry etching process, but the type of etching is not limited thereto.

Referring to FIG. 2, FIG. 16, and FIG. 17, a data conductive layer 60 is deposited on the resultant shown in FIG. 16 (S111). The data conductive layer 60 may be made of a single layer or a multilayer including aluminum (Al), copper (Cu), silver (Ag), molybdenum (Mo), chromium (Cr), titanium (Ti), tantalum (Ta), or an alloy thereof, as mentioned above.

A photoresist film is disposed on the deposited data conductive layer 60 and is patterned to form a third photoresist pattern 103, which may be patterned so as to expose the channel region of the data conductive layer 60.

Referring to FIG. 2, FIG. 3, FIG. 17, and FIG. 18, the third photoresist pattern 103 is used as an etching mask to etch the exposed data conductive layer 60 so that a data wiring having a channel region, for example, a data wiring including a data line (not shown), a source electrode 65, and a drain electrode 66 is formed (S112). Particularly, the insulation substrate 10 having the data conductive layer 60 and the third photoresist pattern 103 formed therein is moved to the etching unit 110, which uses a gas (e.g. Cl-based gas) to dry-etch the data conductive layer 60 and form data wirings.

Referring to FIG. 2, FIG. 3, FIG. 18, and FIG. 19, the etching process is further conducted to remove and separate the resistant contact layer pattern 51 in the channel region so that resistant contact layers 55 and 56 are completed (S112). In order to completely separate the resistant contact layers 55 and 56 in the channel region, the underlying semiconductor layer pattern 41 may be partially over-etched to form a semiconductor layer 44.

As mentioned above with reference to FIG. 11, gas (e.g. Cl gas) may remain on the section of the etched data wirings. Therefore, a cleaning process is performed to remove the gas remaining on the section of the data wirings.

Particularly, after the insulation substrate 10 has been etched by the etching unit 110, it is moved to the waiting unit 120 and waits to be cleaned (S113). During this period the cleaning unit 140 performs a preliminary cleaning operation (S114). Then, the control unit 150 checks the cleaning operation of the cleaning unit 140 (S115). If the cleaning operation is normal, the insulation substrate 10 is transferred to the cleaning unit 140 by the transfer unit 130 so that the main cleaning operation can performed (S116). If the cleaning operation of the cleaning unit 140 is not normal, the abnormal operation is corrected while the insulation substrate 10 waits in the waiting unit 120 (S113). The process then resumes from the preliminary cleaning operation (S14).

This minimizes the time of exposure of the insulation 10 to the air during cleaning, as mentioned above, and reduces corrosive substances formed on the etched data wirings.

After the cleaning process is over, the insulation substrate 10 undergoes substantially the same process as the process of manufacturing a TFT substrate described with reference to FIG. 12, FIG. 13, and FIG. 14. This completes a TFT substrate as shown in FIG. 14.

As mentioned above, the inventive method of manufacturing a TFT substrate and the manufacturing system used in the same have the following advantages.

Firstly, the production of corrosive substances during the process of manufacturing a TFT substrate may be reduced. This reduces the defective ratio of the LCDs.

Secondly, the period for which the TFT substrate waits to be cleaned can be managed efficiently during the manufacturing process.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A method of manufacturing a thin film transistor substrate, the method comprising:
providing an etching unit with an insulation substrate comprising a thin metal film, and dry-etching the insulation substrate to form a circuit pattern;
providing a waiting unit for the insulation substrate waiting to be cleaned;
performing a preliminary cleaning operation by a cleaning unit having a plurality of nozzles while the insulation substrate waits, and checking the preliminary cleaning operation; and
performing a main cleaning operation with regard to the insulation substrate based on a result of the check.

2. The method of claim 1, wherein performing the preliminary cleaning operation comprises:
sensing the insulation substrate in the waiting unit;
performing the preliminary cleaning operation by spraying a cleaning liquid via the nozzles of the cleaning unit when the insulation substrate is in the waiting unit; and
measuring an amount of the cleaning liquid sprayed during the preliminary cleaning operation and comparing the amount with a reference value.

3. The method of claim 2, wherein the preliminary cleaning operation is performed by the cleaning unit, and the cleaning liquid is sprayed via the nozzles for approximately 1-5 seconds while the cleaning unit is not provided with the insulation substrate.

4. The method of claim 2, wherein when the measured amount of the cleaning liquid is substantially equal to or greater than the reference value, the insulation substrate is transferred to the cleaning unit for the main cleaning operation.

5. The method of claim 2, wherein when the measured amount of the cleaning liquid is less than reference value, the insulation substrate remains in the waiting unit.

6. The method of claim 2, wherein the cleaning liquid is high-temperature deionized water.

7. The method of claim 1, wherein a Cl-based gas is used when dry-etching the insulation substrate by the etching unit.

8. The method of claim 1, wherein the etching unit and the waiting unit are in a vacuum state.

9. The method of claim 1, wherein the thin metal film has a multilayered structure comprising Al.

10. The method of claim 9, wherein the thin metal film is a dual film of Al/Mo or a triple film of Mo/Al/Mo.

11. The method of claim 1, further comprising forming a gate wiring and a gate insulation film on an upper surface of the insulation substrate before the insulation substrate is dry-etched so as to form the circuit pattern, the circuit pattern being a data wiring formed on an upper portion of the gate insulation film.

12. A system for manufacturing a thin film transistor substrate, the system comprising:
an etching unit to dry-etch an insulation substrate and a thin metal film deposited on the insulation substrate to form a circuit pattern;
a waiting unit to receive the insulation substrate from the etching unit;
a cleaning unit comprising a plurality of nozzles, the cleaning unit to receive the insulation substrate from the waiting unit and perform a main cleaning operation;
a transfer unit positioned between the waiting unit and the cleaning unit so as to transfer the insulation substrate; and
a control unit to control the cleaning unit to perform a preliminary cleaning operation while the insulation substrate waits in the waiting unit, the control unit to check whether the cleaning unit operates normally and determine the main cleaning operation of the insulation substrate based on a result of the checking.

13. The system of claim 12, wherein the control unit comprises:
a sensing portion to sense when the insulation substrate in the waiting unit;
a driving portion to initiate the preliminary cleaning operation of the cleaning unit when the insulation substrate is in the waiting unit;
a measurement/comparison portion to measure an amount of a cleaning liquid sprayed via the nozzles of the cleaning unit and compare the amount with a reference value; and
a control portion to provide the transfer unit with a signal based on a result of the comparing of the measurement/comparison portion so that transfer of the insulation substrate is controlled.

14. The system of claim 13, wherein the driving portion is adapted to spray the cleaning liquid via the nozzles for approximately 1-5 seconds.

15. The system of claim 13, wherein the cleaning liquid is high-temperature deionized water.

16. The system of claim 13, wherein the control portion is adapted to drive the transfer unit so that the insulation substrate is transferred to the cleaning unit when the amount of the cleaning liquid sprayed via the nozzles is substantially equal to or greater than the reference value.

17. The system of claim 13, wherein the control portion does not drive the transfer unit so that the insulation substrate waits in the waiting unit when the amount of the cleaning liquid sprayed via the nozzles is less than the reference value.

18. The system of claim 12, wherein the etching unit and the waiting unit are in a vacuum state.

19. The system of claim 12, wherein the thin metal film is a multilayer comprising Al, and the etching unit uses a Cl-based gas to etch the thin metal film.

20. The system of claim 12, wherein a gate wiring and a gate insulation film are formed on an upper surface of the insulation substrate, and the circuit pattern is a data wiring formed on an upper portion of the gate insulation film.
